(19) United States
(12) Patent Application Publication
(10) Pub. No.: US 2019/0227719 A1
(43) Pub. Date: Jul. 25, 2019

(54) STORAGE DEVICE AND METHOD OF OPERATING THE SAME

(71) Applicant: SK hynix Inc., Gyeonggi-do (KR)

(72) Inventors: Jeen PARK, Gyeonggi-do (KR); In JUNG, Gyeonggi-do (KR)

(21) Appl. No.: 16/103,413

(22) Filed: Aug. 14, 2018

(30) Foreign Application Priority Data
Jan. 22, 2018 (KR) 10-2018-0007754

(51) Int. Cl. G06F 3/06; G11C 16/26

(52) U.S. Cl. CPC G06F 3/0613; G11C 16/26; G11C 16/0483; G06F 3/0659; G06F 3/0679; G06F 3/0658

(57) ABSTRACT

The storage device includes a memory device including a plurality of planes, and a memory controller configured to store, while the memory device is in a busy state, read requests for different planes among read requests for the memory device as read requests to be processed by the memory device after the busy state of the memory device is terminated.

### CROSS-REFERENCE TO RELATED APPLICATION

The present application claims priority to Korean patent application number 10-2018-0007754, filed on Jan. 22, 2018, which is incorporated herein by reference in its entirety.

### BACKGROUND

### 1. Field of Invention

Various embodiments of the present disclosure generally relate to an electronic device, and more particularly, to a storage device and a method of operating the storage device.

### 2. Description of Related Art

Generally, a storage device is a device which stores data under control of a host device such as a computer, a smartphone, or a smartpad. Examples of storage devices include a device such as a hard disk drive (HDD) which stores data in a magnetic disk, and a device such as a solid-state drive (SSD) or a memory card which stores data in a semiconductor memory, particularly, a nonvolatile memory.

Representative examples of nonvolatile memories include a read only memory (ROM), a programmable ROM (PROM), an electrically programmable ROM (EPROM), an electrically erasable programmable ROM (EEPROM), a flash memory, a phase-change random access memory (PRAM), a magnetic RAM (MRAM), a resistive RAM (RRAM), a ferroelectric RAM (FRAM), etc.

### SUMMARY

Various embodiments of the present disclosure are directed to a storage device configured to perform a multi-plane read operation, and a method of operating the storage device.

An embodiment of the present disclosure provides a storage device including: a memory device including a plurality of planes; and a memory controller configured to store, while the memory device is in a busy state, read requests for different planes among read requests for the memory device as read requests to be processed by the memory device after the busy state of the memory device is terminated.

An embodiment of the present disclosure provides a memory controller configured to control a memory device including a plurality of planes, the memory controller including: a host controller configured to receive read requests for the memory device from an external host; a flash translation layer configured to store, while the memory device is in a busy state, read requests for different planes among the read requests for the memory device as read requests to be processed by the memory device after the busy state of the memory device is terminated; and a flash controller configured to provide, to the memory device, addresses and a read command which correspond to the read requests provided from the flash translation layer.

An embodiment of the present disclosure provides a method of operating a memory controller configured to control a memory device including a plurality of planes, the method including: receiving read requests for the memory device from a host; determining whether the memory device is in a busy state; and performing a multi-plane read operation on the memory device depending on a result of the determining.

### BRIEF DESCRIPTION OF THE DRAWINGS

FIG. 1 is a diagram illustrating a storage device in accordance with an embodiment of the present disclosure.

FIG. 2 is a diagram illustrating memory devices each including a different number of planes in accordance with an embodiment of the present disclosure.

FIG. 3 is a diagram illustrating functionally-divided components of the memory controller of FIG. 1 in accordance with an embodiment of the present disclosure.

FIG. 4 is a diagram illustrating a multi-plane read controller of FIG. 3 in accordance with an embodiment of the present disclosure.

FIG. 5 is a diagram illustrating a multi-plane read operation in accordance with an embodiment of the present disclosure.

FIG. 6 is a flowchart illustrating an operation of the memory controller in accordance with an embodiment of the present disclosure.

FIG. 7 is a diagram illustrating a configuration of the memory device of FIG. 1 in accordance with an embodiment of the present disclosure.

FIG. 8 is a diagram illustrating a memory cell array of FIG. 7 in accordance with an embodiment of the present disclosure.

FIG. 9 is a schematic circuit diagram illustrating a configuration of a memory block of the memory cell array of FIG. 8 in accordance with an embodiment of the present disclosure.

FIG. 10 is a schematic circuit diagram illustrating a configuration of a memory block of the memory cell array of FIG. 8 in accordance with an embodiment of the present disclosure.

FIG. 11 is a schematic circuit diagram illustrating a configuration of a memory block of the memory cell array of FIG. 8 in accordance with an embodiment of the present disclosure.

FIG. 12 is a block diagram illustrating an example of the memory controller of FIG. 1 in accordance with an embodiment of the present disclosure.

FIG. 13 is a block diagram illustrating a memory card system to which a storage device in accordance with an embodiment of the present disclosure is applied.

FIG. 14 is a block diagram illustrating a solid state drive (SSD) system to which the storage device in accordance with an embodiment of the present disclosure is applied.

FIG. 15 is a block diagram illustrating a user system to which the storage device in accordance with an embodiment of the present disclosure is applied.

### DETAILED DESCRIPTION

Example embodiments of the present invention will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present.

Hereinafter, embodiments will be described with reference to the accompanying drawings. Embodiments are described herein with reference to cross-sectional illustrations that are schematic illustrations of embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but may include deviations in shapes that result, for example, from manufacturing. In the drawings, lengths and sizes of layers and regions may be exaggerated for clarity. Like reference numerals in the drawings denote like elements.

Terms such as “first” and “second” may be used to describe various components, but they should not limit the various components. Those terms are only used for the purpose of differentiating a component from other components. For example, a first component may be referred to as a second component, and a second component may be referred to as a first component and so forth without departing from the spirit and scope of the present disclosure. Furthermore, “and/or” may include any one of or a combination of the components mentioned.

Furthermore, a singular form may include a plural from as long as it is not specifically mentioned in a sentence. Furthermore, “include/comprise” or “including/comprising” used in the specification represents that one or more components, steps, operations, and elements exist or are added.

Furthermore, unless defined otherwise, all the terms used in this specification including technical and scientific terms have the same meanings as would be generally understood by those skilled in the related art. The terms defined in generally used dictionaries should be construed as having the same meanings as would be construed in the context of the related art, and unless clearly defined otherwise in this specification, should not be construed as having idealistic or overly formal meanings.

It is also noted that in this specification, “connected/coupled” refers to one component not only directly coupling another component but also indirectly coupling another component through an intermediate component. On the other hand, “directly connected/directly coupled” refers to one component directly coupling another component without an intermediate component.

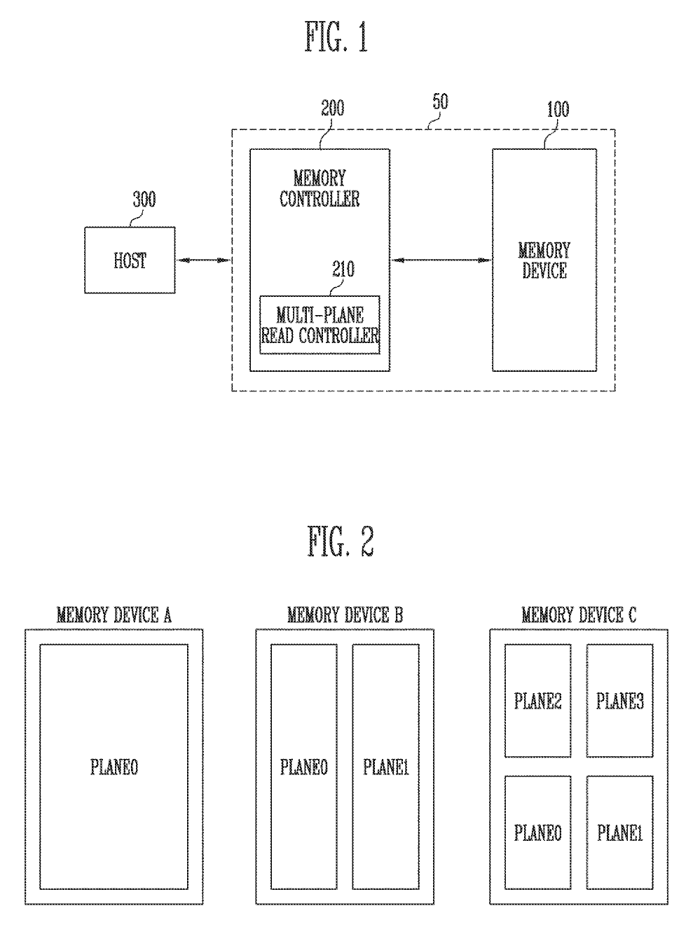

FIG. 1 is a diagram illustrating a storage device 50 in accordance with an embodiment of the present disclosure.

Referring to FIG. 1, the storage device 50 may include memory device 100 and memory controller 200 operatively coupled to each other via a communication channel.

The memory device 100 may store data therein. The memory device 100 may operate under the control of the memory controller 200. The memory device 100 may include a memory cell array including a plurality of memory cells configured to store data therein. The memory cell array may include a plurality of memory blocks. Each memory block may include a plurality of memory cells. The memory device 100 may store data to a memory block in a sequential or random order under control of the memory controller 200. In various embodiments, the memory device 100 may be a double data rate synchronous dynamic random access memory (DDR SDRAM), a low power double data rate4 (LPDDR4) SDRAM, a graphics double data rate (GDDR) SDRAM, a low power DDR (LPDDR), a rambus dynamic random access memory (RDRAM), a NAND flash memory, a vertical NAND flash memory, a NOR flash memory device, a resistive random access memory (RRAM), a phase-change memory (PRAM), a magnetoresistive random access memory (MRAM), a ferroelectric random access memory (FRAM), or a spin transfer torque random access memory (STT-RAM). In various embodiments, the memory device 100 may be embodied in a three-dimensional array structure. The present disclosure may be applied not only to a flash memory in which a charge storage layer is formed of a conductive floating gate (FG), but also to a charge trap flash (CTF) memory in which a charge storage layer is formed of an insulating layer.

The memory device 100 may be configured to receive a command and an address from the memory controller 200 and access a region of the memory cell array which is selected by the address. In other words, the memory device 100 may perform an operation corresponding to the command on the memory region selected by the address. For example, the memory device 100 may perform at least one of a write (program) operation, a read operation, and an erase operation. During a program operation, the memory device 100 may program data to the region selected by the address. During a read operation, the memory device 100 may read data from the region selected by the address. During an erase operation, the memory device 100 may erase data from the region selected by the address.

The memory controller 200 may control an operation of the memory device 100 in response to a request of a host 300. The memory controller 200 may also control an operation of the memory device 100 without receiving a request of the host 300.

For example, the memory controller 200 may control the memory device 100 to perform a program operation, a read operation, or an erase operation in response to a request received from the host 300. During a program operation, the memory controller 200 may provide a program command, a physical address, and data to the memory device 100. During a read operation, the memory controller 200 may provide a read command and a physical address to the memory device 100. During the erase operation, the memory controller 200 may provide an erase command and a physical address to the memory device 100. The physical address may correspond to a logical address received from the host 300.

In various embodiments the memory controller 200 may autonomously generate a program command, an address, and data without a request received from the host 300, and may transmit them to the memory device 100. For example, the memory controller 200 may provide a command, an address and data to the memory device 100 to perform background operations such as a wear leveling, or a garbage collection operation.

The memory controller 200 may execute firmware for controlling the memory device 100. For example, in various embodiments the memory device 100 may be a flash memory device, and the memory controller 200 may manage firmware such as a flash translation layer (FTL) for controlling communication between the host 300 and the memory device 100. For example, the memory controller 200 may translate a logical address included in a request received from the host 300 to a physical address corresponding to a physical memory region.

In various embodiments, the memory device 100 may include a plurality of planes. Each of the planes may include a plurality of memory blocks. Multiple operations may be performed in parallel (i.e., simultaneously) on memory blocks of different planes according to a multi-plane operation. The multi-plane operation may perform various processing operations on different planes simultaneously. In various embodiments, a plane may be the unit of memory region which is accessed when a program operation, a read operation, or an erase operation is performed. Therefore, in a multi-plane structure in which the memory device 100 includes a plurality of planes, the erase operation, the read operation, or the program operation may be performed on blocks or pages disposed in different planes at the same time.

As illustrated in the embodiment of FIG. 1, the memory controller 200 may include a multi-plane read controller 210. The multi-plane read controller 210 may control the performance of simultaneous read operations on a plurality of planes included in the memory device 100. For example, the multi-plane read controller 210 may provide multiple read requests one for each different plane to the memory device 100 to perform a multi-plane read operation on the memory device 100, and may thus control the memory device 100 such that an operation of simultaneously reading a plurality of planes is possible.

In various embodiments of the present disclosure, the multi-plane read controller 210 may perform the multi-plane read operation in an interleaving manner. More specifically, the multi-plane read controller 210 may pair read requests for different planes of the same memory device 100, and control the memory device 100 to simultaneously perform the paired read requests in the interleaving manner. In various embodiments, the multi-plane read controller 210 may perform a pairing operation on read requests which are received from the host 300 when the memory device 100 is in a busy state.

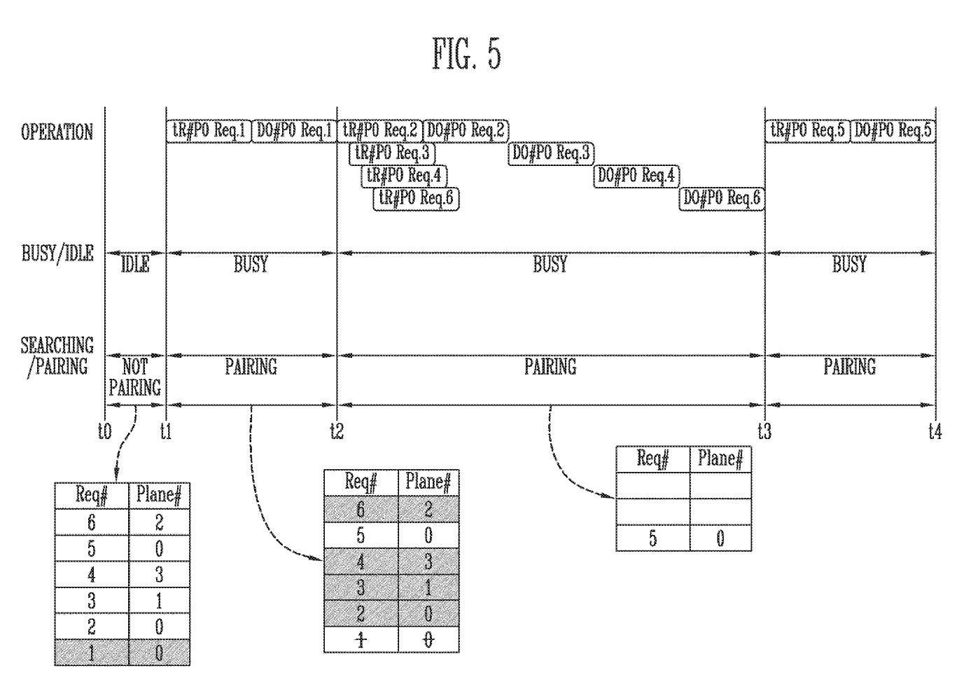

The multi-plane read operation in accordance with an embodiment of the present disclosure will be described in more detail later herein with reference to FIGS. 3 to 6.

The host 300 may communicate with the storage device 50 using at least one of various communication methods such as universal serial bus (USB), serial AT attachment (SATA), serial attached SCSI (SAS), high speed interchip (HSIC), small computer system interface (SCSI), peripheral component interconnection (PCI), PCI express (PCIe), nonvolatile memory express (NVMe), universal flash storage (UFS), secure digital (SD), multimedia card (MMC), embedded MMC (eMMC), dual in-line memory module (DIMM), registered DIMM (RDIMM), and load reduced DIMM (LRDIMM) communication methods.

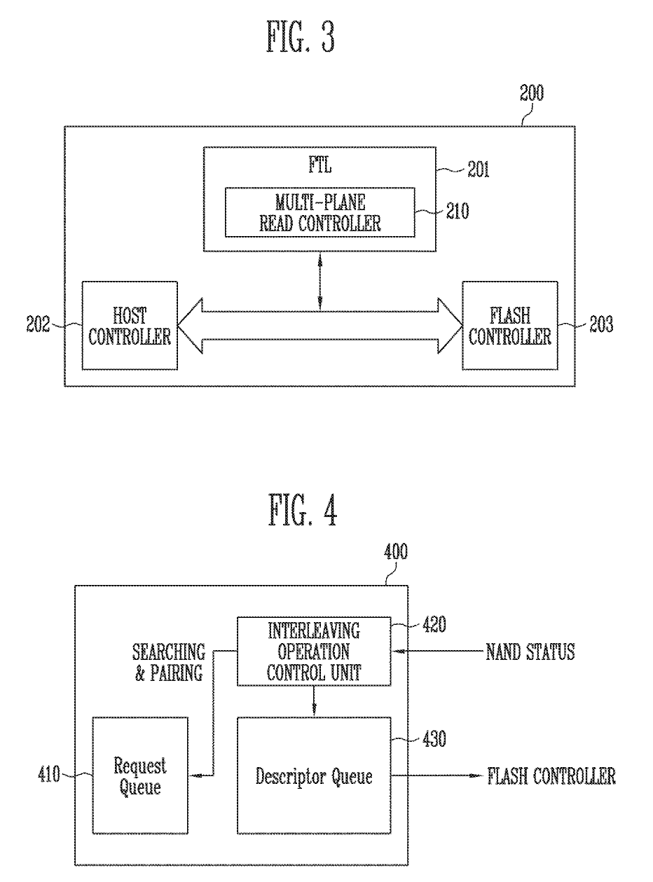

FIG. 2 is a diagram illustrating memory devices, each including a different number of planes in accordance with an embodiment of the present disclosure.

Referring to FIG. 2, memory device A is a single plane memory device including one plane PLANE0. Memory devices B and C are multi-plane memory devices including two planes PLANE0 and PLANE1, and four planes PLANE0, PLANE1, PLANE2, and PLANE3, respectively.

Each of the planes may include a plurality of memory blocks. To process in parallel operations on the memory blocks, a multi-plane memory device may perform a multi-plane operation of simultaneously processing operations on a plurality of planes. In various embodiments, a plane may be the unit of memory region which is accessed when a program operation, a read operation, or an erase operation is performed. Therefore, each of the multi-plane memory devices may simultaneously perform the erase operation, the read operation, or the program operation on blocks or pages disposed in different planes.

In various embodiments, the multi-plane memory device may include one or more dedicated peripheral circuits for each of the respective planes of the multi-plane memory device for simultaneously accessing the planes.

In various other embodiments, the multi-plane memory device may include a single peripheral circuit capable of simultaneously accessing the respective planes of the multi-plane memory device, and also include separate dedicated storage spaces corresponding to the respective planes.

To perform a multi-plane operation by the multi-plane memory device, addresses of planes to be accessed during each operation must differ from each other. In other words, because the multi-plane operation is an operation of performing in parallel operations on different planes, operations cannot be performed on the same plane as a multi-plane operation.

FIG. 3 is a diagram illustrating functionally-divided components of the memory controller 200 of FIG. 1 according to an embodiment of the disclosure.

Referring to FIG. 3, the memory controller 200 may include a flash translation layer (FTL) 201, a host controller 202, and a flash controller 203. The FTL 201 may be firmware. In other words, the FTL 201 may be firmware configured to perform overall operations for controlling communication between the host 300 and a flash memory device 100 (refer to FIG. 1).

In various embodiments, the FTL 201 may translate a logical address included in a request received from the host 300 into a physical address. In various embodiments, the physical address may be an address indicating a specific memory region included in the flash memory device 100.

In various embodiments, the FTL 201 may control operations for wear-leveling. For example, the FTL 201 may manage wear-levels of memory blocks included in the flash memory device 100. Memory cells of the flash memory device 100 may be aged by repeated program operations and erase operations on the memory blocks. An aged memory cell, i.e., a worn memory cell, may cause a defect (e.g., a physical defect). Therefore, the FTL 201 may manage the memory blocks such that respective erase-write cycle counts of the blocks are equalized across the various memory blocks to prevent a specific memory block of the flash memory device 100 from being worn earlier than the other memory blocks are.

In various embodiments, the FTL 201 may control operations for garbage collection. The garbage collection may be a background operation of collecting valid data included in each of a plurality of memory blocks into a memory block having the same address so as to secure usable free blocks.

The host controller 202 may communicate with the host 300. In various embodiments, the host controller 202 may communicate with the host 300 using at least one of various communication methods such as universal serial bus (USB), serial AT attachment (SATA), serial attached SCSI (SAS), high speed interchip (HSIC), small computer system interface (SCSI), peripheral component interconnection (PCI), PCI express (PCIe), nonvolatile memory express (NVMe), universal flash storage (UFS), secure digital (SD), multiMedia card (MMC), embedded MMC (eMMC), dual in-line memory module (DIMM), registered DIMM (RDIMM), and load reduced DIMM (LRDIMM) communication methods.

The host controller 202 may provide read requests received from the host 300 to the FTL 201.

The host controller 202 may provide, to the host 300, results of operations performed in response to the read requests received from the host 300.

The flash controller 203 may communicate with the flash memory device 100. In various embodiments, the flash controller 203 may communicate with the flash memory device 100 through any one communication interface of a NAND flash or a NOR flash. The flash controller 203 may provide, to the flash memory device 100, read commands corresponding to read requests received from the FTL 201. The flash controller 203 may receive results of operations, performed by the flash memory device 100 in response to the read commands.

In various embodiments of the present disclosure, the FTL 201 may include the multi-plane read controller 210.

The multi-plane read controller 210 may control a read operation on the flash memory device 100 including a plurality of planes. For example, the multi-plane read controller 210 may pair requests which may be serviced by a multi-plane operation among a plurality of read requests input for the flash memory device 100.

In various embodiments, the multi-plane read controller 210 may determine whether to perform the pairing operation depending on information about conditions of the flash memory device 100 provided from the flash controller 203. For example, when the flash memory device 100 is in an idle state, the multi-plane read controller 210 may provide a read request having the highest priority to the memory controller 200 without performing the pairing operation. When the flash memory device 100 is in a busy state, the multi-plane read controller 210 may pair requests which may be serviced by a multi-plane operation among a plurality of read requests input to the flash memory device 100. The multi-plane read controller 210 may provide paired requests to the flash controller 203.

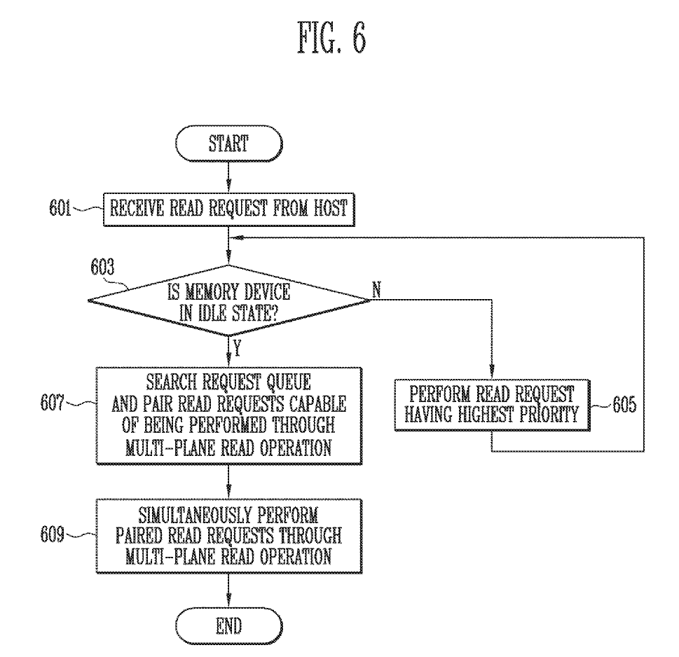

FIG. 4 is a diagram illustrating an example of the multi-plane read controller 210 of FIG. 3 in accordance with an embodiment of the present disclosure.

Referring to FIG. 4, the multi-plane read controller 400 may include a request queue 410, an interleaving operation control unit 420, and a descriptor queue 430.

The request queue 410 may store read requests received from the host 300, according to an input sequence. The request queue 410 may be controlled by the FTL 201 described with reference to FIG. 3. For example, the FTL 201 may translate a logical address included in a read request inputted from the host 300 into a physical address, and input the translated physical address to the request queue 410. The physical address may include a plane address.

The interleaving operation control unit 420 may search for read requests included in the request queue 410 depending on a flash memory device status NAND STATUS. The interleaving operation control unit 420 may pair read requests for different plane addresses of the same flash memory device 100 among the read requests included in the request queue 410 in a multi-plane read request.

The interleaving operation control unit 420 may store the paired read requests to a descriptor queue 430. The descriptor queue 430 may be provided to the flash controller 203 described with reference to FIG. 3.

The flash controller 203 may sequentially process the read requests which are included in the descriptor queue 430 received from the multi-plane read controller 400.

In various embodiments, only when the flash memory device status NAND STATUS is in a busy state, the interleaving operation control unit 420 may search for read requests included in the request queue 410 and pair read requests for different planes of the same flash memory device 100 in multi-plane read request to be processed simultaneously after the busy state is terminated.

In various embodiments, when the flash memory device status NAND STATUS is in an idle state, the interleaving operation control unit 420 may not pair read requests for which are included in the request queue 410. Instead, when the flash memory device status NAND STATUS is in the idle state, the interleaving operation control unit 420 may sequentially store the read requests which are in the request queue 410 into the descriptor queue 430 according to their priority status which may also be stored in the request queue. For example, the interleaving operation control unit 420 may store a read request having the highest priority among the read requests included in the request queue 410 to the descriptor queue 430. The interleaving operation control unit 420 may also store the remaining read requests according to a descending priority order into the descriptor queue 430.

In various embodiments of the present disclosure, while servicing read requests stored in the descriptor queue 430, the flash controller 203 may search for read requests to be performed through a multi-plane read operation among read requests stored in the request queue 410, and pair the searched read requests. In this way, the operating efficiency regarding the multi-plane read operation may be improved further.

FIG. 5 is a diagram illustrating a multi-plane read operation in accordance with an embodiment of the present disclosure.

Referring to FIG. 5, read requests inputted to the request queue 410 during a period t0 to t1 may include first to sixth requests. A plane address of each of the first, the second, and the fifth requests is plane 0, a plane address of the third request is plane 1, a plane address of the fourth request is plane 3, and a plane address of the sixth request is plane 2.

FIG. 5 illustrates, by way of an example, the case where the memory controller 200 performs a multi-plane read operation on a single memory device, e.g., memory device 100. Furthermore, it is assumed that the memory device 100 includes four planes, i.e., planes 0 to 3.

It is further assumed that at time t0 the memory device 100 may be in an idle state. Therefore, the memory controller may input a read request corresponding to a first inputted request to the descriptor queue 430 without performing request queue searching and pairing operations. The memory device 100 may service, during a period t1 to t2, the first request inputted to the descriptor queue 430. In a variation, instead of transferring the first read request that was inputted into the request queue into the descriptor queue 430, the memory controller may transfer the highest priority read request among the read requests that are inputted in the request queue 410 into the descriptor queue 430.

Hence, during a period t1 to t2, the memory device 100 may be in a busy state because it is performing the previously inputted first request (or highest priority request). While the memory device is in the busy state, the memory controller 200 may search the request queue 410 for read requests and pair the read requests in a multi-plane read request based on their plane addresses. More specifically, while the memory device is in the busy state, the memory controller 200 may search the request queue 410 for read requests and group the read requests which have different plane addresses in a multi-plane read request. In the illustrated example among the read requests included in the request queue in the period t1 to t2, the second request is a read request for plane 0, the third request is a read request for plane 1, the fourth request is a read request for plane 3, the fifth request is for plane 0, and the sixth request is a read request for plane 2. Hence, the second, the third, the fourth, and the sixth requests which relate to different plane addresses may be grouped as a single multi-plane read request. The memory controller 200 may then input the read multi-plane request which includes the second, the third, the fourth, and the sixth requests to the descriptor queue 450. The memory device 100 may then perform (or “service”), through a multi-plane read operation, the second, the third, the fourth, and the sixth requests which was inputted as a multi-plane read request into the descriptor queue 450.

During a period t2 to t3, the memory device 100 may be in a busy state because it is performing the second, the third, the fourth, and the sixth requests through the multi-plane read operation. Therefore, the memory controller 200 may search the request queue for read requests and pair the read requests having different plane addresses in a multi-plane read request. In the illustrated example, because only the fifth read request is included in the request queue during the period t2 to t3, no pairing is performed. When additional read requests for different plane addresses are inputted to the request queue 410, the memory controller 200 may pair read requests for different plane addresses in a multi-plane read request.

The memory device 100 may enter an idle state again after the read operation corresponding to the second, the third, the fourth, and the sixth requests has been completed and the corresponding data have been outputted. When the memory device 100 returns in the idle state, the memory controller 200 may then input the fifth request included in the request queue 410 to the descriptor queue 430 without performing the request queue searching and pairing operation. Consequently, during a period t3 to t4, the memory device 100 may perform the fifth request input to the descriptor queue 450 and the memory device 100 may enter a busy state at a point in time t3.

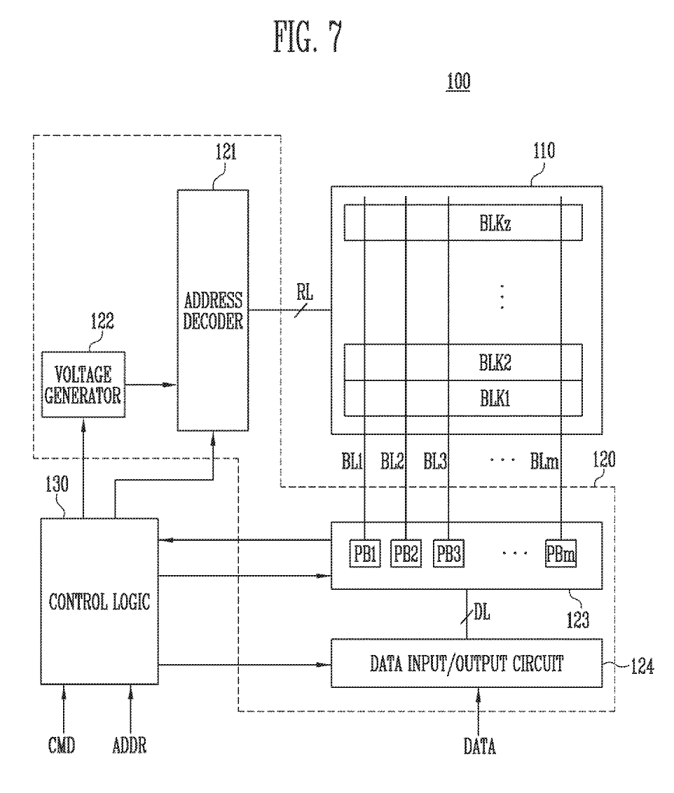

FIG. 6 is a flowchart illustrating an operation of the memory controller 200 in accordance with an embodiment of the present disclosure.

Referring to FIG. 6, at step 601, the memory controller 200 may receive a read request from the host 300. In detail, the memory controller 200 may translate a logical address included in the read request into a physical address, and input the translated physical address to the request queue 410. The physical address may include a plane address.

At step S603, the memory controller 200 may determine whether the memory device 100 is in an idle state.

The idle state may be a state in which the memory device 100 is not performing an operation. Alternatively, the idle state may be a state in which the memory device 100 performs an access operation on a memory region included therein but does not perform communication with the memory controller 200. As a result of the determination, if the memory device 100 is in an idle state, the processor proceeds to step 607. If the memory device 100 is not in the idle state, then the process proceeds to step 605.

At step 605, the memory controller 200 may process a read request which has the highest priority. In detail, the memory controller 200 may input, to the descriptor queue 430, a read request having the is highest priority among the read requests which have been inputted into the request queue 410, and provide the descriptor queue 430 to the flash controller 203. The flash controller 203 may sequentially process the read requests according to the provided descriptor queue 450. The flash controller 203 may provide read commands and addresses to the memory device 100 to perform the read requests. In various embodiments, the memory controller 200 may input the read requests to the descriptor queue 430 in a sequence in which the read requests have been inputted to the request queue 410.

At step 607, the memory controller 200 may search the request queue for read requests, and pair the read requests in a multi-plane read request that can be served through a multi-plane read operation. For example, the memory controller 200 may pair read requests having different plane addresses in a multi-plane read request.

At step 609, the memory controller 200 may simultaneously process the paired read requests of the multi-plane read request through a multi-plane read operation.

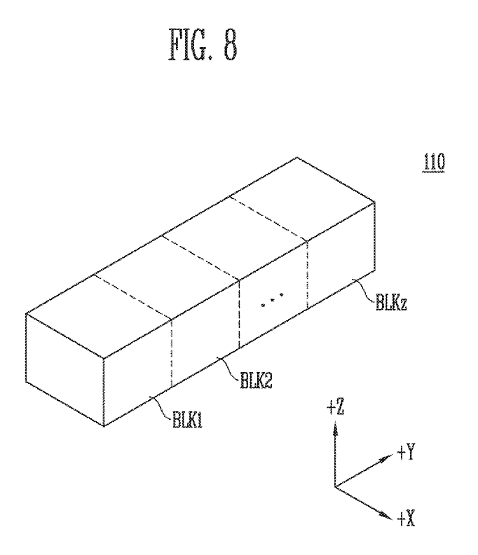

FIG. 7 is a diagram illustrating the configuration of the memory device 100 of FIG. 1 according to an embodiment.

Referring to FIG. 7, the memory device 100 may include a memory cell array 110, a peripheral circuit 120, and a control logic 130.

The memory cell array 110 may include a plurality of memory blocks BLK1 to BLKz. The plurality of memory blocks BLK1 to BLKz are coupled to the address decoder 121 through row lines RL. The memory is blocks BLK1 to BLKz may be coupled to the read/write circuit 123 through bit lines BL1 to BLm. Each of the memory blocks BLK1 to BLKz may include a plurality of memory cells. In various embodiments, the plurality of memory cells may be nonvolatile memory cells. Memory cells coupled to the same word line among the plurality of memory cells are defined as one page. In other words, the memory cell array 110 is formed of a plurality of pages. In various embodiments, each of the memory blocks BLK1 to BLKz included in the memory cell array 110 may include a plurality of dummy cells. Here, one or more dummy cells may be coupled in series between a drain select transistor and memory cells and between a source select transistor and the memory cells.

Each of the memory cells of the memory device 100 may be formed of a single level cell (SLC) capable of storing a single data bit, a multi-level cell (MLC) capable of storing two data bits, a triple-level cell (TLC) capable of storing three data bits, or a quad-level cell (QLC) capable of storing four data bits.

The peripheral circuit 120 may include an address decoder 121, a voltage generator 122, a read/write circuit 123, and a data input/output circuit 124.

The peripheral circuit 120 may drive the memory cell array 110. For example, the peripheral circuit 120 may drive the memory cell array 110 to perform a program operation, a read operation, or an erase operation.

The address decoder 121 is coupled to the memory cell array 110 through the row lines RL. The row lines RL may include drain select lines, word lines, source select lines, and a common source line. In various embodiments, the word lines may include normal word lines and dummy word lines. In various embodiments, the row lines RL may further include a pipe select line.

The address decoder 121 may operate under control of the control logic 130. The address decoder 121 may receive addresses ADDR from the control logic 130.

The address decoder 121 may decode a block address among the received addresses ADDR. The address decoder 121 selects at least one of the memory blocks BLK1 to BLKz according to the decoded block address. The address decoder 121 may decode a row address among the received addresses ADDR. The address decoder 121 may select at least one word line WL of the selected memory block by applying voltages supplied from the voltage generator 122 to the at least one word line WL according to the decoded row address.

During a program operation, the address decoder 121 may apply a program voltage to a selected word line and apply a pass voltage having a level lower than that of the program voltage to unselected word lines. During a program verify operation, the address decoder 121 may apply a verify voltage to a selected word line and apply a verify pass voltage higher than the verify voltage to unselected word lines.

During a read operation, the address decoder 121 may apply a read voltage to a selected word line and apply a pass voltage higher than the read voltage to unselected word lines.

In various embodiments, an erase operation of the memory device 100 may be performed on a memory block basis. During the erase operation, an address ADDR to be inputted to the memory device 100 includes a block address. The address decoder 121 may decode the block address and select a corresponding one memory block according to the decoded block address. During the erase operation, the address decoder 121 may apply a ground voltage to word lines coupled to the selected memory block.

In various embodiments, the address decoder 121 may decode a column address among the transmitted addresses ADDR. A decoded column address DCA may be transmitted to the read/write circuit 123. In various embodiments, the address decoder 121 may include components such as a row decoder, a column decoder, and an address buffer.

The voltage generator 122 may generate a plurality of voltages using an external power voltage supplied to the memory device 100. The voltage generator 122 is operated under control of the control logic 130.

In various embodiments, the voltage generator (122) may generate an internal supply voltage by regulating an external supply voltage. The internal supply voltage generated from the voltage generator 122 may be used as an operating voltage of the memory device 100.

In various embodiments, the voltage generator 122 may produce a plurality of voltages using the external supply voltage or the internal supply voltage. The voltage generator 122 may generate various voltages required in the memory device 100. For example, the voltage generator 122 may generate a plurality of program voltages, a plurality of pass voltages, a plurality of select read voltages, and a plurality of unselect read voltages.

For example, the voltage generator 122 may include a plurality of pumping capacitors for receiving the internal supply voltage, and generate a plurality of voltages by selectively enabling the plurality of pumping capacitors under control of the control logic 130.

The generated voltages may be supplied to the memory cell array 110 by the address decoder 121.

The read/write circuit 123 may include first to m-th page buffers PB1 to PBm. The first to m-th page buffers PB1 to PBm are coupled to the memory cell array 110 through the first to m-th bit lines BL1 to BLm, respectively. The first to m-th page buffers PB1 to PBm may operate under control of the control logic 130.

The first to m-th page buffers PB1 to PBm may perform data communication with the data input/output circuit 124. During a program operation, the first to m-th page buffers PB1 to PBm may receive data to be stored through the data input/output circuit 124 and data lines DL.

During a program operation, the first to m-th page buffers PB1 to PBm may transmit the data, received through the data input/output circuit 124, to selected memory cells through the bit lines BL1 to BLm when a program pulse is applied to a selected word line. The memory cells in the selected page are programmed based on the transmitted data. Memory cells coupled to a bit line to which a program allowable voltage (e.g. a ground voltage) is applied may have increased threshold voltages. Threshold voltages of memory cells coupled to a bit line to which a program inhibit voltage (for example, a supply voltage) is applied may be retained. During a program verify operation, the first to m-th page buffers PB1 to PBm may read page data from selected memory cells through the bit lines BL1 to BLm.

During a read operation, the read/write circuit 123 may read data from the memory cells in the selected page through the bit lines BL, and output the read data to the data input/output circuit 124.

During an erase operation, the read/write circuit 123 may float the bit lines BL. In various embodiments, the read/write circuit 123 may include a row select circuit.

The data input/output circuit 124 is coupled to the first to m-th page buffers PB1 to PBm through the data lines DL. The data input/output circuit 124 may operate under control of the control logic 130.

The data input/output circuit 124 may include a plurality of input/output buffers (not shown) which receive input data. During a program operation, the data input/output circuit 124 may receive data DATA to be stored from an external controller (not shown). During a read operation, the data input/output circuit 124 may output, to the external controller, the data received from the first to m-th page buffers PB1 to PBm included in the read/write circuit 123.

The control logic 130 may be coupled to the address decoder 121, the voltage generator 122, the read/write circuit 123, and the data input/output circuit 124. The control logic 130 may control the overall operation of the memory device 100. The control logic 130 may operate in response to a command CMD transmitted from an external device.

In various embodiments, the memory device 100 of FIG. 7 may be any one of the planes included in the memory devices (memory devices A to C) described with reference to FIG. 2. In various embodiments, the memory cell array 110 and the read/write circuit 123 of FIG. 7 may form a single plane.

FIG. 8 is a diagram illustrating an example of the memory cell array of FIG. 7 in accordance with an embodiment of the present disclosure.

Referring to FIG. 8, the memory cell array 110 may include a plurality of memory blocks BLK1 to BLKz. Each memory block may have a three-dimensional structure. Each memory block may include a plurality of memory cells stacked on a substrate. The memory cells are arranged in a +X direction, a +Y direction, and a +Z direction. The structure of each memory block will be described in more detail with reference to FIGS. 4 and 5.

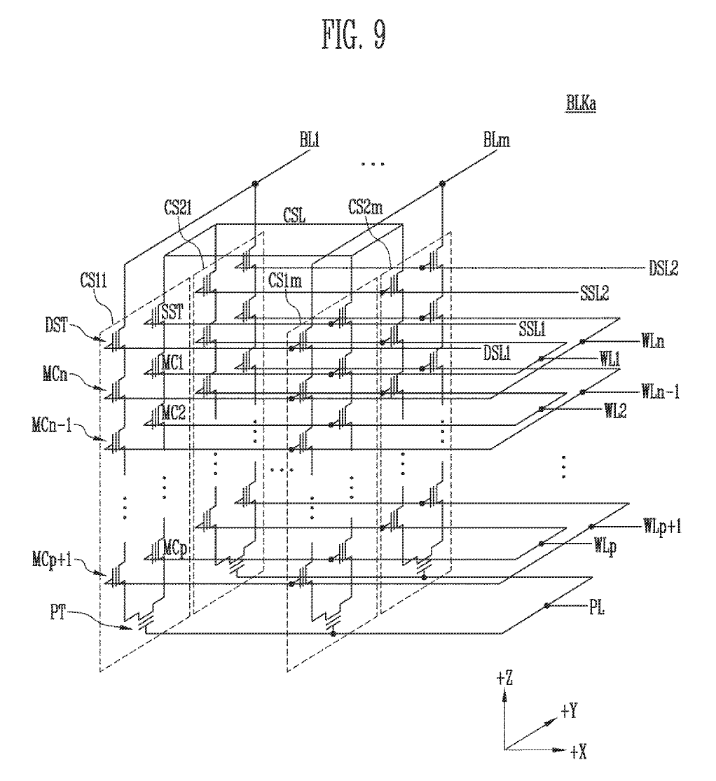

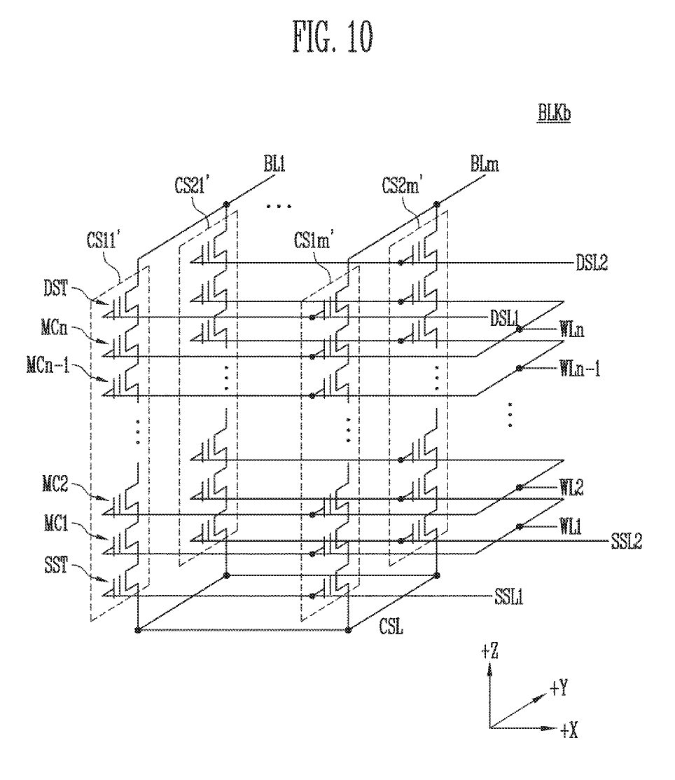

FIG. 9 is a circuit diagram illustrating any one (BLKa) of memory blocks (BLK1) to (BLKz) of FIG. 8 in accordance with an embodiment of the present disclosure.

Referring to FIG. 9, the memory block BLKa may include a plurality of cell strings CS11 to CS1m and CS21 to CS2m. In various embodiments, each of the cell strings CS11 to CS1m and CS21 to CS2m may be formed in a ‘U’ shape. In the memory block BLKa, m cell strings may be arranged in a row direction (i.e., the +X direction). In FIG. 9, two cell strings are illustrated as being arranged in a column direction (i.e., the +Y direction). However, this illustration is made for convenience of description, and it will be understood that three or more cell strings may be arranged in the column direction.

Each of the plurality of cell strings CS11 to CS1m and CS21 to CS2m may include at least one source select transistor SST, first to n-th memory cells MC1 to MCn, a pipe transistor PT, and at least one drain select transistor DST.

The select transistors SST and DST and the memory cells MC1 to MCn may have structures similar to each other. In various embodiments, each of the select transistors SST and DST and the memory cells MC1 to MCn may include a channel layer, a tunneling insulating layer, a charge storage layer, and a blocking insulating layer. In various embodiments, a pillar for providing the channel layer may be provided in each cell string. In various embodiments, a pillar for providing at least one of the channel layer, the tunneling insulating layer, the charge storage layer, and the blocking insulating layer may be provided in each cell string.

The source select transistor SST of each cell string is coupled between the common source line CSL and the memory cells MC1 to MCp.

In various embodiments, source select transistors of cell strings arranged in the same row are coupled to a source select line extending in a row direction, and source select transistors of cell strings arranged in different rows are coupled to different source select lines. In FIG. 9, source select transistors of the cell strings CS11 to CS1m in a first row are coupled to a first source select line SSL1. Source select transistors of the cell strings CS21 to CS2m in a second row are coupled to a second source select line SSL2.

In various embodiments, the source select transistors of the cell strings CS11 to CS1m and CS21 to CS2m may be coupled in common to a single source select line.

The first to n-th memory cells MC1 to MCn in each cell string are coupled between the source select transistor SST and the drain select transistor DST.

The first to n-th memory cells MC1 to MCn may be divided into first to p-th memory cells MC1 to MCp and p+1-th to n-th memory cells MCp+1 to MCn. The first to p-th memory cells MC1 to MCp are successively arranged in a direction opposite to the +Z direction and are coupled in series between the source select transistor SST and the pipe transistor PT. The p+1-th to n-th memory cells MCp+1 to MCn are successively arranged in the +Z direction and are coupled in series between the pipe transistor PT and the drain select transistor DST. The first to p-th memory cells MC1 to MCp and the p+1-th to n-th memory cells MCp+1 to MCn are coupled to each other through the pipe transistor PT. The gates of the first to n-th memory cells MC1 to MCn of each cell string are coupled to first to n-th word lines WL1 to WLn, respectively.

A gate of the pipe transistor PT of each cell string is coupled to a pipeline PL.

The drain select transistor DST of each cell string is coupled between the corresponding bit line and the memory cells MCp+1 to MCn. The cell strings arranged in the row direction are coupled to drain select lines extending in the row direction. Drain select transistors of the cell strings CS11 to CS1m in the first row are coupled to a first drain select line DSL1. Drain select transistors of the cell strings CS21 to CS2m in the second row are coupled to a second drain select line DSL2.

Cell strings arranged in the column direction may be coupled to bit lines extending in the column direction. In FIG. 9, cell strings CS11 and CS21 in a first column are coupled to a first bit line BL1. Cell strings CS1m and CS2m in an m-th column are coupled to an m-th bit line BLm.

Memory cells coupled to the same word line in cell strings arranged in the row direction form a single page. For example, memory cells coupled to the first word line WL1, among the cell strings CS11 to CS1m in the first row, form a single page. Memory cells coupled to the first word line WL1, among the cell strings CS21 to CS2m in the second row, form another single page. Cell strings arranged in the direction of a single row may be selected by selecting any one of the drain select lines DSL1 and DSL2. One page may be selected from among the selected cell strings by selecting any one of the word lines WL1 to WLn.

In various embodiments, even bit lines and odd bit lines may be provided in lieu of the first to m-th bit lines BL1 to BLm. Even-number-th cell strings of the cell strings CS11 to CS1m or CS21 to CS2m arranged in the row direction may be coupled to respective even bit lines. Odd-number-th cell strings of the cell strings CS11 to CS1m or CS21 to CS2m arranged in the row direction may be coupled to respective odd bit lines.

In various embodiments, at least one or more of the first to n-th memory cells MC1 to MCn may be used as a dummy memory cell. For example, the at least one or more dummy memory cells may be provided to reduce an electric field between the source select transistor SST and the memory cells MC1 to MCp. Alternatively, the at least one or more dummy memory cells may be provided to reduce an electric field between the drain select transistor DST and the memory cells MCp+1 to MCn. As the number of dummy memory cells is increased, the reliability in operation of the memory block BLKa may be increased, while the size of the memory block BLKa may be increased. As the number of dummy memory cells is reduced, the size of the memory block BLKa may be reduced, but the reliability in operation of the memory block BLKa may be reduced.

To efficiently control the at least one dummy memory cells, each of the dummy memory cells may have a required threshold voltage. Before or after an erase operation on the memory block BLKa is performed, program operations may be performed on all or some of the dummy memory cells. In the case where an erase operation is performed after a program operation has been performed, the dummy memory cells may have required threshold voltages by controlling a voltage to be applied to the dummy word lines coupled to the respective dummy memory cells.

FIG. 10 is a circuit diagram illustrating any one BLKb of memory blocks BLK1 to BLKz of FIG. 8 in accordance with an embodiment of the present disclosure.

Referring to FIG. 10, a memory block BLKb may include a plurality of cell strings CS11′ to CS1m′ and CS21′ to CS2m′. Each of the cell strings CS11′ to CS1m′ and CS21′ to CS2m′ extends in the +Z direction. Each of the cell strings CS11′ to CS1m′ and CS21′ to CS2m′ may include at least one source select transistor SST, first to nth memory cells MC1 to MCn, and at least one drain select transistor DST which are stacked on a substrate (not shown) provided in a lower portion of the memory block BLK1′.

The source select transistor SST of each cell string is coupled between the common source line CSL and the memory cells MC1 to MCn. The source select transistors of cell strings arranged in the same row are coupled to the same source select line. Source select transistors of the cell strings CS11′ to CS1m′ arranged in a first row may be coupled to a first source select line SSL1. Source select transistors of the cell strings CS21′ to CS2m′ arranged in a second row may be coupled to a second source select line SSL2. In various embodiments, source select transistors of the cell strings CS11′ to CS1m′ and CS21′ to CS2m′ may be coupled in common to a single source select line.

The first to n-th memory cells MC1 to MCn in each cell string are coupled in series between the source select transistor SST and the drain select transistor DST. Gates of the first to nth memory cells MC1 to MCn are respectively coupled to first to n-th word lines WL1 to WLn.

The drain select transistor DST of each cell string is coupled between the corresponding bit line and the memory cells MC1 to MCn. Drain select transistors of cell strings arranged in the row direction may be coupled to drain select lines extending in the row direction. Drain select transistors of the cell strings CS11′ to CS1m′ in the first row are coupled to a first drain select line DSL1. Drain select transistors of the cell strings CS21′ to CS2m′ in the second row may be coupled to a second drain select line DSL2.

Consequentially, the memory block BLKb of FIG. 10 may have an equivalent circuit similar to that of the memory block BLKa of FIG. 9 except that a pipe transistor PT is excluded from each cell string.

In various embodiments, even bit lines and odd bit lines may be provided in lieu of the first to m-th bit lines BL1 to BLm. Even-number-th cell strings among the cell strings CS11′ to CS1m′ or CS21′ to CS2m′ arranged in the row direction may be coupled to the respective even bit lines, and odd-number-th cell strings among the cell strings CS11′ is to CS1m′ or CS21′ to CS2m′ arranged in the row direction may be coupled to the respective odd bit lines.

In various embodiments, at least one or more of the first to n-th memory cells MC1 to MCn may be used as a dummy memory cell. For example, the at least one or more dummy memory cells may be provided to reduce an electric field between the source select transistor SST and the memory cells MC1 to MCn. Alternatively, the at least one or more dummy memory cells may be provided to reduce an electric field between the drain select transistor DST and the memory cells MC1 to MCn. As the number of dummy memory cells is increased, the reliability in operation of the memory block BLKb may be increased, while the size of the memory block BLKb may be increased. As the number of dummy memory cells is reduced, the size of the memory block BLKb may be reduced, but the reliability in operation of the memory block BLKb may be reduced.

To efficiently control the at least one dummy memory cells, each of the dummy memory cells may have a required threshold voltage. Before or after an erase operation on the memory block BLKb is performed, program operations may be performed on all or some of the dummy memory cells. In the case where an erase operation is performed after a program operation has been performed, the dummy memory cells may have required threshold voltages by controlling a voltage to be applied to the dummy word lines coupled to the respective dummy memory cells.

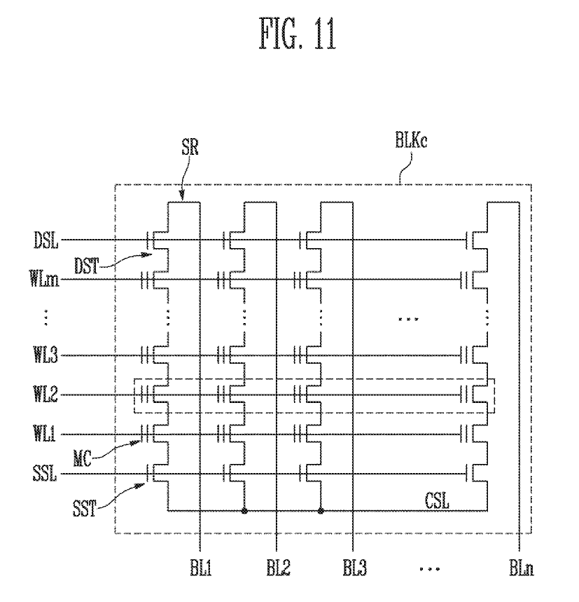

FIG. 11 is a circuit diagram illustrating any one BLKc of the memory blocks BLK1 to BLKz included in the memory cell array 110 of FIG. 7 in accordance with an embodiment of the present disclosure.

Referring to FIG. 11, the memory block BKLc may include a plurality of strings SR. The plurality of strings SR may be respectively coupled to a plurality of bit lines BL1 to BLn. Each string SR may include a source select transistor SST, memory cells MC, and a drain select transistor DST.

The source select transistor SST of each string SR may be coupled between the memory cells MC and a common source line CSL. The source select transistors SST of the strings SR may be coupled in common to the common source line CSL.

The drain select transistor DST of each string SR may be coupled between the memory cells MC and the corresponding bit line BL. The drain select transistors DST of the strings SR may be respectively coupled the bit lines BL1 to BLn.

In each string SR, a plurality of memory cells MC may be provided between the source select transistor SST and the drain select transistor DST. In each string SR, the memory cells MC may be coupled in series with each other.

In the strings SR, memory cells MC disposed in the same turn from the common source line CSL may be coupled in common to a single word line. The memory cells MC of the strings SR may be coupled to a plurality of word lines WL1 to WLm.

In the memory block BLKc, an erase operation may be performed on a memory block basis. When the erase operation is performed on a memory block basis, all memory cells of the memory block BLKc may be simultaneously erased in response to an erase request.

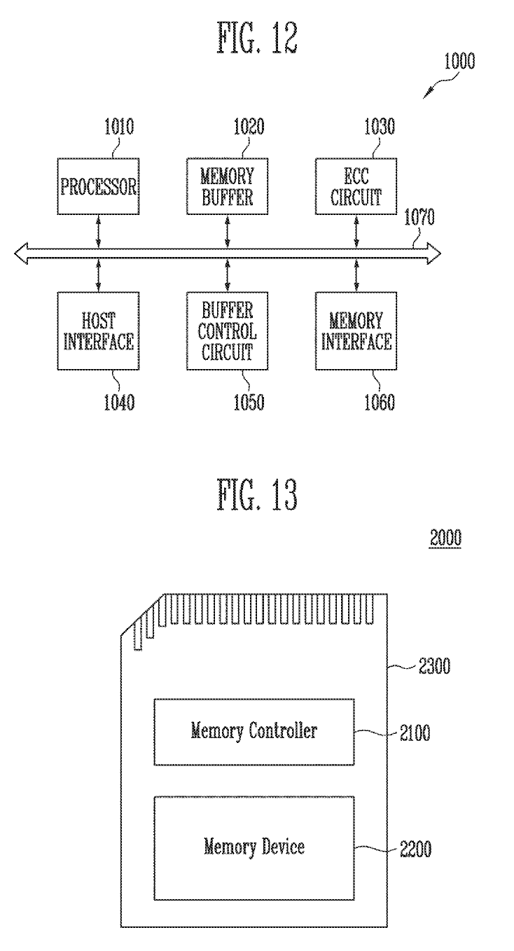

FIG. 12 is a block diagram illustrating an example of the memory controller 200 of FIG. 1 in accordance with an embodiment of the present disclosure.

The memory controller 1000 is coupled to the host 300 and the memory device 100. In response to a request received from the host 300, the controller 1000 may access the memory device 100. For example, the memory controller 1000 may control a write operation, a read operation, an erase operation, and a background operation of the memory device 100. The memory controller 1000 may provide an interface between the memory device 100 and the host 300. The memory controller 1000 may drive firmware for controlling the memory device 100.

Referring to FIG. 12, the memory controller 1000 may include a processor 1010, a memory buffer 1020, an error correction code (ECC) circuit 1030, a host interface 1040, a buffer control circuit 1050, a memory interface 1060, and a bus 1070.

The bus 1070 may provide a channel between the components of the memory controller 1000.

The processor 1010 may control the overall operation of the memory controller 1000 and perform a logical operation. The processor 1010 may communicate with the external host through the host interface 1040, and communicate with the memory device 100 through the memory interface 1060. In addition, the processor 1010 may communicate with the memory buffer 1020 through the buffer control circuit 1050. The processor 1010 may control the operation of the storage device 50 using the memory buffer 1020 as an operation memory, a cache memory, or a buffer memory.

The processor 1010 may perform the function of a flash translation layer (FTL). The processor 1010 may translate a logical block address (LBA), provided by the host, into a physical block address (PBA) through the FTL. The FTL may receive the LBA using a mapping table and translate the LBA into the PBA. An address mapping method using the FTL may be modified in various ways based on the unit of mapping. Representative address mapping methods may include a page mapping method, a block mapping method, and a hybrid mapping method.

The processor 1010 may randomize data received from the host. For example, the processor 1010 may use a randomizing seed to randomize data received from the host. Randomized data may be provided to the memory device 100 as data to be stored, and may be programmed to the memory cell array.

During a read operation, the processor 1010 may derandomize data received from the memory device 100. For example, the processor 1010 may use a derandomizing seed to derandomize data received from the memory device 100. Derandomized data may be output to the host.

In various embodiments, the processor 1010 may drive software or firmware to perform the randomizing operation or the derandomizing operation.

In various embodiments, the processor 1010 may perform the operation of the multi-plane read controller 210 or 400 described with reference to FIGS. 1, 3, and 4.

The memory buffer 1020 may be used as an operation memory, a cache memory, or a buffer memory of the processor 1010. The memory buffer 1020 may store codes and commands to be executed by the processor 1010. The memory buffer 1020 may store data to be processed by the processor 1010. The memory buffer 1020 may include a static RAM (SRAM) or a dynamic RAM (DRAM).

The ECC circuit 1030 may perform error correction. The ECC circuit 1030 may perform an ECC encoding operation based on data to be written to the memory device 100 through the memory interface 1060. ECC encoded data may be transmitted to the memory device 100 through the memory interface 1060. The ECC circuit 1030 may perform an ECC decoding operation on data received from the memory device 100 through the memory interface 1060. For example, the ECC circuit 1030 may be included in the memory interface 1060 as a component of the memory interface 1060.

The host interface 1040 may communicate with the external host under control of the processor 1010. The host interface 1040 may is perform communication using at least one of various communication methods such as a universal serial bus (USB), a serial AT attachment (SATA), a serial attached SCSI (SAS), a high speed interchip (HSIC), a small computer system interface (SCSI), a peripheral component interconnection (PCI), a PCI express (PCIe), a nonvolatile memory express (NVMe), a universal flash storage (UFS), a secure digital (SD), multiMedia card (MMC), an embedded MMC (eMMC), a dual in-line memory module (DIMM), a registered DIMM (RDIMM), and a load reduced DIMM (LRDIMM). In various embodiments, the host interface 1040 may be included in the host controller 202 described with reference to FIG. 3.

The buffer control circuit 1050 may control the memory buffer 1020 under control of the processor 1010.

The memory interface 1060 may communicate with the memory device 100 under control of the processor 1010. The memory interface 1060 may communicate a command, an address, and data with the memory device 100 through the channel. In various embodiments, the memory interface 1060 may be included in the flash controller 203 described with reference to FIG. 3.

For example, the memory controller 1000 may include neither the memory buffer 1020 nor the buffer control circuit 1050.

For example, the processor 1010 may use codes to control the operation of the memory controller 1000. The processor 1010 may load codes from a nonvolatile memory device (e.g., a read only memory) provided in the memory controller 1000. Alternatively, the processor 1010 may load codes from the memory device 100 through the memory interface 1060.

For example, the bus 1070 of the memory controller 1000 may be divided into a control bus and a data bus. The data bus may transmit data in the memory controller 1000. The control bus may transmit control information such as a command and an address in the memory controller 1000. The data bus and the control bus may be separated from each other and may neither interfere with each other nor affect each other. The data bus may be coupled to the host interface 1040, the buffer control circuit 1050, the ECC circuit 1030, and the memory interface 1060. The control bus may be coupled to the host interface 1040, the processor 1010, the buffer control circuit 1050, the memory buffer 1020, and the memory interface 1060.

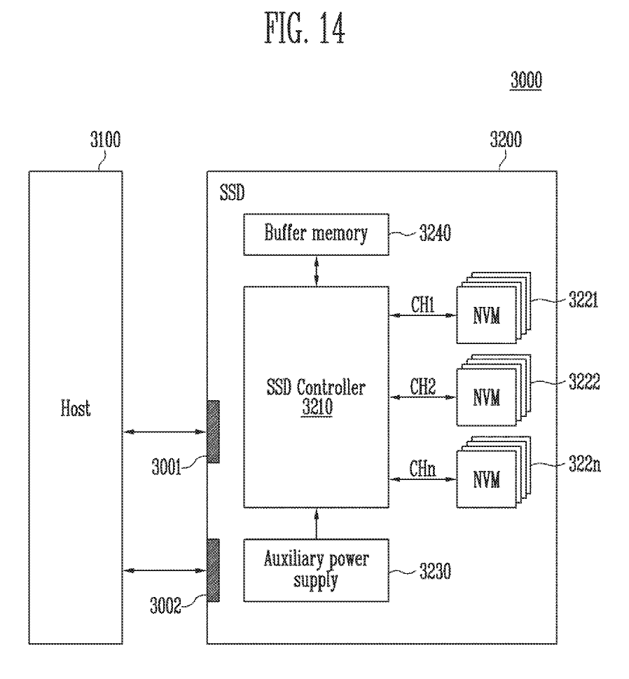

FIG. 13 is a block diagram illustrating a memory card system 2000 to which a storage device in accordance with an embodiment of the present disclosure is applied.

Referring FIG. 13, the memory card system 2000 may include a memory controller 2100, a memory device 2200 and a connector 2300.

The memory controller 2100 is coupled to the memory device 2200. The memory controller 2100 may access the memory device 2200. For example, the memory controller 2100 may control a read operation, a write operation, an erase operation, and a background operation of the memory device 2200. The memory controller 2100 may provide an interface between the memory device 2100 and the host. The memory controller 2100 may drive firmware for controlling the memory device 2200. The memory controller 2100 may be embodied in the same manner as that of the memory controller 200 described with reference to FIG. 1.

In various embodiments, the memory controller 2100 may include components such as a random-access memory (RAM), a processing unit, a host interface, and a memory interface, and an ECC circuit.

The memory controller 2100 may communicate with an external device through the connector 2300. The memory controller 2100 may communicate with an external device (e.g., a host) based on a specific communication protocol. In various embodiments, the memory controller 2100 may communicate with the external device through at least one of various communication protocols such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer small interface (SCSI), enhanced small disk interface (ESDI), integrated drive electronics (IDE), Firewire, universal flash storage (UFS), Wi-Fi, Bluetooth, and nonvolatile memory express (NVMe) protocols. In various embodiments, the connector 2300 may be defined by at least one of the above-described various communication protocols.

In various embodiments, the memory device 2200 may be implemented as any of various nonvolatile memory devices, such as an electrically erasable and programmable ROM (EEPROM), a NAND flash memory, a NOR flash memory, a phase-change RAM (PRAM), a resistive RAM (ReRAM), a ferroelectric RAM (FRAM), and a spin-torque magnetic RAM (STT-MRAM).

In various embodiments, the memory controller 2100 and the memory device 2200 may be integrated into a single semiconductor device to form a memory card. For example, the memory controller 2100 and the memory device 2200 may be integrated into a single semiconductor device to form a memory card such as a personal computer memory card international association (PCMCIA), a compact flash card (CF), a smart media card (SM or SMC), a memory stick, a multimedia card (MMC, RS-MMC, or MMCmicro), a SD card (SD, miniSD, microSD, or SDHC), or a universal flash storage (UFS).

In various embodiments, the memory device 2200 may be operated in the same manner as that of the memory device 100 described with reference to FIGS. 1, and 7 to 11.

FIG. 14 is a block diagram illustrating a solid state drive (SSD) system 3000 to which the storage device in accordance with an embodiment of the present disclosure is applied.

Referring to FIG. 14, the SSD system 3000 may include a host 3100 and an SSD 3200. The SSD 3200 may exchange signals SIG with the host 3100 through a signal connector 3001 and may receive power PWR through a power connector 3002. The SSD 3200 may include an SSD controller 3210, a plurality of flash memories 3221 to 322n, an auxiliary power supply 3230, and a buffer memory 3240.

In various embodiments, the SSD controller 3210 may perform the function of the memory controller 200, described above with reference to FIG. 1.

The SSD controller 3210 may control the plurality of flash memories 3221 to 322n in response to the signals SIG received from the host 3100. In various embodiments, the signals SIG may be signals based on the interfaces of the host 3100 and the SSD 3200. For example, the signals SIG may be signals defined by at least one of various interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer small interface (SCSI), enhanced small disk interface (ESDI), integrated drive electronics (IDE), Firewire, universal flash storage (UFS), Wi-Fi, Bluetooth, and nonvolatile memory express (NVMe) interfaces.

The auxiliary power supply 3230 may be coupled to the host 3100 through the power connector 3002. The auxiliary power supply 3230 may be supplied with power PWR from the host 3100 and may be charged. The auxiliary power supply 3230 may supply the power of the SSD 3200 when the supply of power from the host 3100 is not smoothly performed. In various embodiments, the auxiliary power supply 3230 may be positioned inside the SSD 3200 or positioned outside the SSD 3200. For example, the auxiliary power supply 3230 may be disposed in a main board and may supply auxiliary power to the SSD 3200.

The buffer memory 3240 functions as a buffer memory of the SSD 3200. For example, the buffer memory 3240 may temporarily store data received from the host 3100 or data received from the plurality of flash memories 3221 to 322n or may temporarily store metadata (e.g., mapping tables) of the flash memories 3221 to 322n. The buffer memory 3240 may include volatile memories such as DRAM, SDRAM, DDR SDRAM, LPDDR SDRAM, and GRAM or nonvolatile memories such as FRAM, ReRAM, STT-MRAM, and PRAM.

In various embodiments, the flash memories 3221 to 322n may be operated in the same manner as that of the memory device 100 described with reference to FIGS. 1, and 7 to 11.

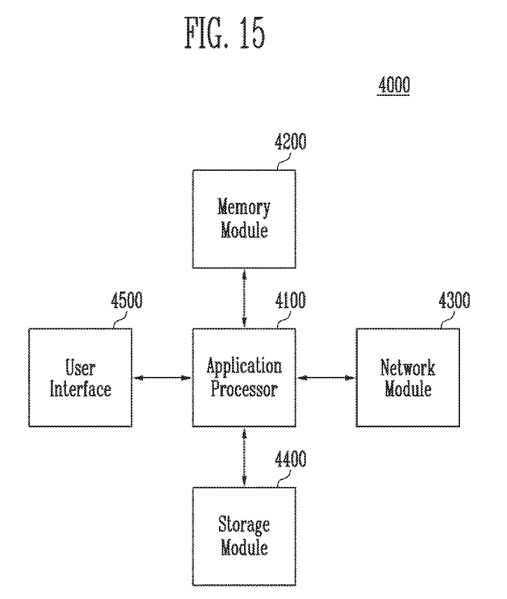

FIG. 15 is a block diagram illustrating a user system 4000 to which the storage device in accordance with an embodiment of the present disclosure is applied.

Referring to FIG. 15, the user system 4000 may include an application processor 4100, a memory module 4200, a network module 4300, a storage module 4400, and a user interface 4500.

The application processor 4100 may run components included in the user system 4000, an operating system (OS) or a user program. In various embodiments, the application processor 4100 may include controllers, interfaces, graphic engines, etc. for controlling the components included in the user system 4000. The application processor 4100 may be provided as a system-on-chip (SoC).

The memory module 4200 may function as a main memory, a working memory, a buffer memory or a cache memory of the user system 4000. The memory module 4200 may include volatile RAMs such as DRAM, SDRAM, DDR SDRAM, DDR2 SDRAM, DDR3 SDRAM, LPDDR SDARM, and LPDDR3 SDRAM, or nonvolatile RAMs such as PRAM, ReRAM, MRAM, and FRAM. In various embodiments, the application processor 4100 and the memory module 4200 may be packaged based on package-on-package (POP) and may then be provided as a single semiconductor package.

The network module 4300 may communicate with external devices. For example, the network module 4300 may support wireless communication, such as code division multiple access (CDMA), global system for mobile communication (GSM), wideband CDMA (WCDMA), CDMA-2000, time division multiple access (TDMA), long term evolution (LTE), WiMAX, WLAN, UWB, Bluetooth, or Wi-Fi communication. In various embodiments, the network module 4300 may be included in the application processor 4100.

The storage module 4400 may store data therein. For example, the storage module 4400 may store data received from the application processor 4100. Alternatively, the storage module 4400 may transmit the data stored in the storage module 4400 to the application processor 4100. In various embodiments, the storage module 4400 may be implemented as a nonvolatile semiconductor memory device, such as a phase-change RAM (PRAM), a magnetic RAM (MRAM), a resistive RAM (RRAM), a NAND flash memory, a NOR flash memory, or a NAND flash memory having a three-dimensional (3D) structure. In various embodiments, the storage module 4400 may be provided as a removable storage medium (i.e., removable drive), such as a memory card or an external drive of the user system 400.

In various embodiments, the storage module 4400 may include a plurality of nonvolatile memory devices, and each of the plurality of nonvolatile memory devices may be operated in the same manner as that of the memory device 100, described above with reference to FIGS. 1 to 5. The storage module 4400 may be operated in the same manner as that of the storage device 50, described above with reference to FIG. 1.

The user interface 4500 may include interfaces which input data or instructions to the application processor 4100 or output data to an external device. In various embodiments, the user interface 4500 may include user input interfaces such as a keyboard, a keypad, a button, a touch panel, a touch screen, a touch pad, a touch ball, a camera, a microphone, a gyroscope sensor, a vibration sensor, and a piezoelectric device. The user interface 4500 may further include user output interfaces such as an a liquid crystal display (LCD), an organic light emitting diode (OLED) display device, an active matrix OLED (AMOLED) display device, an LED, a speaker, and a motor.

Various embodiments of the present disclosure provide a storage device configured to perform a multi-plane read operation in an improved manner, and a method of operating the storage device.

While the exemplary embodiments of the present disclosure have been disclosed for illustrative purposes, those skilled in the art will appreciate that various modifications, additions and substitutions are possible. Therefore, the scope of the present disclosure is defined by the appended claims and equivalents of the claims rather than by the description preceding them.

In the above-discussed embodiments, some of the described steps may be skipped without departing from the scope of the present invention. In addition, the steps in each embodiment may not always be performed in the described order. Furthermore, the embodiments disclosed in the present specification and the drawings aims to help those with ordinary knowledge in this art more clearly understand the present disclosure rather than aiming to limit the bounds of the present disclosure. In other words, one of ordinary skill in the art to which the present disclosure belongs will be able to easily understand that various modifications are possible based on the technical scope of the present disclosure.

Embodiments of the present disclosure have been described with reference to the accompanying drawings, and specific terms or words used in the description should be construed in accordance with the spirit of the present disclosure without limiting the subject matter thereof. It should be understood that many variations and modifications of the basic inventive concept described herein will still fall within the spirit and scope of the present disclosure as defined in the appended claims and their equivalents.

What is claimed is:

1. A storage device comprising:
a memory device including a plurality of planes; and
a memory controller configured to:
store, while the memory device is in a busy state, read requests for different planes among read requests for the memory device as read requests to be processed by the memory device after the busy state of the memory device is terminated.

2. The storage device according to claim 1, wherein the memory controller comprises:
a request queue configured to sequentially store at least one or more read requests for the memory device;
a descriptor queue configured to store read requests to be performed by the memory device among the at least one or more read requests stored in the request queue; and
an interleaving operation control unit configured to pair read requests for different planes among the at least one or more read requests while the memory device is in the busy state, and input the paired read requests to the descriptor queue.

3. The storage device according to claim 2, wherein, when the memory device is in an idle state, the interleaving operation control unit stores, to the descriptor queue, a read request having a highest priority among the at least one or more read requests stored in the request queue.

4. The storage device according to claim 2, wherein, when the memory device is in an idle state, the interleaving operation control unit stores the at least one or more read requests stored in the request queue to the descriptor queue in a sequence in which the at least one or more read requests have been stored in the request queue.

5. The storage device according to claim 2, wherein the memory controller further comprises a flash controller configured to provide, to the memory device, addresses and a read command which correspond to the read requests stored in the descriptor queue.

6. The storage device according to claim 5, wherein the flash controller provides a multi-plane read command and addresses to the memory device such that the paired read requests are simultaneously performed.

7. The storage device according to claim 6, wherein the memory device performs a read operation corresponding to the paired read requests in an interleave manner.

8. A memory controller configured to control a memory device including a plurality of planes, the memory controller comprising:
a host controller configured to receive read requests for the memory device from an external host;
a flash translation layer configured to store, while the memory device is in a busy state, read requests for different planes among the read requests for the memory device as read requests to be processed by the memory device after the busy state of the memory device is terminated; and
a flash controller configured to provide, to the memory device, addresses and a read command which correspond to the read requests provided from the flash translation layer.

9. The memory controller according to claim 8, wherein the flash translation layer comprises:
a request queue configured to sequentially store the read requests for the memory device;
a descriptor queue configured to store read requests to be performed by the memory device among the read requests stored in the request queue; and
an interleaving operation control unit configured to pair read requests for different planes among the read requests while the memory device is in the busy state, and input the paired read requests to the descriptor queue.

10. The memory controller according to claim 9, wherein, when the memory device is in an idle state, the interleaving operation control unit stores, to the descriptor queue, a read request having a highest priority among the read requests stored in the request queue.

11. The memory controller according to claim 9, wherein, when the memory device is in an idle state, the interleaving operation control unit stores the read requests stored in the request queue to the descriptor queue in a sequence in which the read requests have been stored to the request queue.

12. The memory controller according to claim 9, wherein the flash controller provides a multi-plane read command and addresses to the memory device such that the paired read requests are simultaneously performed.

13. The memory controller according to claim 10, wherein the flash controller provides, to the memory device, addresses and a read command which correspond to the read requests stored in the flash translation layer.

14. A method of operating a memory controller configured to control a memory device including a plurality of planes, the method comprising:
receiving read requests for the memory device from a host;
determining whether the memory device is in a busy state; and
performing a multi-plane read operation on the memory device depending on a result of the determining.

15. The method according to claim 14, wherein the performing comprises:
storing, when the memory device is in the busy state, paired read requests obtained by pairing read requests for different planes among the read requests for the memory device, to a descriptor queue to be processed after the busy state is terminated; and
processing the read requests stored in the descriptor queue.

16. The method according to claim 14, wherein the performing comprises:
storing, when the memory device is not in the busy state, the read requests to the descriptor queue to be processed by the memory device, in a sequence in which the read requests have been input from the host; and
processing the read requests stored in the descriptor queue.
